(19) United States
(12) Patent Application Publication
(10) Pub. No.: US 2026/0293339 A1
(43) Pub. Date: Sep. 24, 2026

(54) Image Sensors with Vertical Transfer Gates

(71) Applicant: SEMICONDUCTOR COMPONENTS INDUSTRIES, LLC, Scottsdale, AZ (US)

(72) Inventors: David James COLLINS, Newburgh, NY (US); Santosh MENON, Portland, OR (US); Gang LIU, Camas, WA (US)

(73) Assignee: SEMICONDUCTOR COMPONENTS INDUSTRIES, LLC, Scottsdale, AZ (US)

(21) Appl. No.: 19/444,062

(22) Filed: Jan. 8, 2026

Related U.S. Application Data
(60) Provisional application No. 63/774,501, filed on Mar. 19, 2025.

(51) Int. Cl. H10F 39/00; H04N 25/77

(52) U.S. Cl. CPC H10F 39/80373; H04N 25/77; H10F 39/014

(57) ABSTRACT

An image sensor pixel may include one or more step shield vertical transfer gates that transfer charge generated by a photodiode to a floating diffusion region. The step shield vertical transfer gates may include first portions with first gate oxide thicknesses and second portions with second gate oxide thicknesses that are less than the first thickness. The first portions may be interposed between the photodiode and the second portions. Due to the difference in gate oxide thickness, the first portion may have a higher threshold voltage (Vt) than the second portion. The difference in Vt may steer the charge from the photodiode to the floating diffusion region and may reduce or prevent spill back of the charge to the photodiode when the step shield vertical transfer gates are turned off. The step shield vertical transfer gates may extend partially or entirely through a substrate of the image sensor pixel.

### CROSS-REFERENCE TO RELATED APPLICATIONS

This application claims the benefit of U.S. Provisional Patent Application No. 63/774,501, filed on Mar. 19, 2025, the entire contents of which is incorporated herein by reference.

### BACKGROUND

This relates generally to imaging devices, and more particularly, to imaging devices with vertical transfer gates.

Image sensors are commonly used in electronic devices such as cellular telephones, cameras, and computers, and/or other systems to capture images. In a typical arrangement, an image sensor is provided with an array of image pixels arranged in pixel rows and pixel columns.

Conventional image sensors may include pixels with photodiodes and transfer gates to transfer charge generated by the photodiodes. However, these transfer gates may transfer charge slowly and/or incompletely, and/or the transfer gates may result in a large pixel footprint. For example, charge may spill back from the transfer gate into the photodiode when the transfer gate is turned off, resulting in an incomplete transfer of the charge.

It is within this context that the embodiments described herein arise.

### BRIEF DESCRIPTION OF THE DRAWINGS

FIG. 1 is a schematic diagram of an illustrative electronic device with an image sensor that may include vertical transfer gates in accordance with some embodiments.

FIG. 2 is a diagram of an illustrative pixel with step shield vertical transfer gates in accordance with some embodiments.

FIG. 3 is a diagram of an illustrative circuit of a pixel in accordance with some embodiments.

FIGS. 4A-4E are diagrams of illustrative method steps that may be used to form a pixel with step shield vertical transfer gates in accordance with some embodiments.

FIG. 5 is a diagram of an illustrative pixel with deep trench step shield vertical transfer gates in accordance with some embodiments.

### DETAILED DESCRIPTION

Embodiments of the present technology relate to image sensors having image sensor pixels with vertical transfer gates. In particular, the image sensor pixels may include step shield vertical transfer gates having multiple regions, each with a different gate oxide thickness, to create a threshold voltage (Vt) difference across the transfer gates. The Vt difference may improve the speed of charge transfer between a photodiode of the pixel and a floating diffusion region of the pixel, as well as prevent spill back when the transfer gates are turned off due to the internal potential difference of the transfer gate.

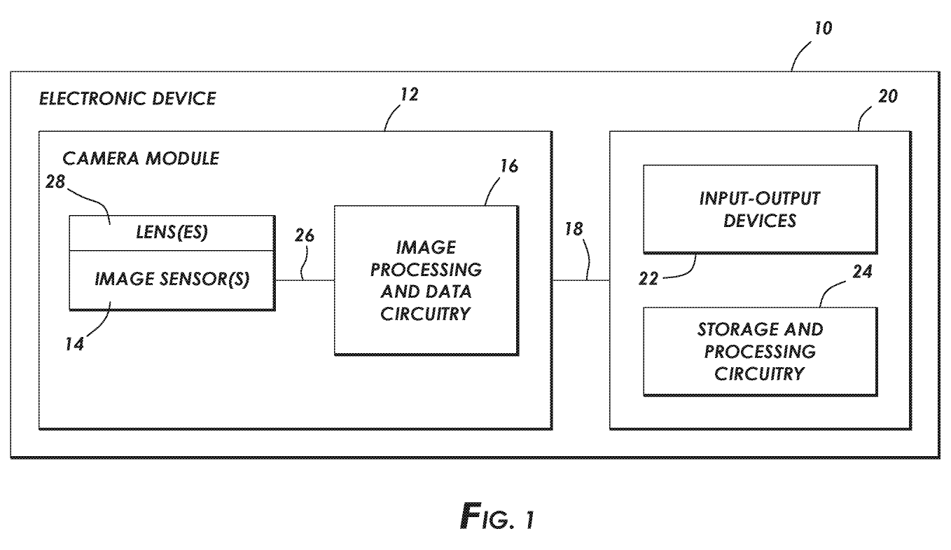

Image sensor pixels with step shield vertical transfer gates may be incorporated into any suitable imaging device. An illustrative electronic device with an image sensor into which image sensor pixels with step shield vertical transfer gates may be incorporated is shown in FIG. 1.

Electronic device 10 (sometimes referred to as an imaging system or an imaging device) of FIG. 1 may be a digital camera, a computer, a cellular telephone, a medical device, or other electronic device. Additionally or alternatively, electronic device 10 may be a broader system and/or incorporated into a broader system, such as a vehicle or building.

Camera module 12 (sometimes referred to as an imaging module) may include one or more image sensors 14 and one or more lenses 28. During operation, lenses 28 may focus light onto image sensor 14. Image sensor 14 includes photosensitive elements (e.g., pixels) that convert the light into digital data. For example, each of the pixels may include a photodiode that generates charge (e.g., photocurrent) in response to incident light, and the generated charge may be converted into the digital data using circuitry in the pixels and/or in camera module 12.

Image sensors may have any number of pixels (e.g., hundreds, thousands, millions, or more). A typical image sensor may, for example, have millions of pixels (e.g., megapixels) arranged in an array, such as a two-dimensional array of the pixels. Additionally, image sensor 14 may include bias circuitry (e.g., source follower load circuits), sample and hold circuitry, correlated double sampling (CDS) circuitry, amplifier circuitry, analog-to-digital (ADC) converter circuitry, data output circuitry, memory (e.g., buffer circuitry), address circuitry, etc., which may be used to generate image data in response to the charge generated by the photodiode.

Still and video image data from image sensor 14 may be provided to image processing and data formatting circuitry 16, such as via path 26. Image processing and data formatting circuitry 16 may be used to perform image processing functions such as automatic focusing functions, depth sensing, data formatting, adjusting white balance and exposure, implementing video image stabilization, face detection, etc. For example, during automatic focusing operations, image processing and data formatting circuitry 16 may process data gathered by three-dimensional imaging pixels in image sensor 14 to determine the magnitude and direction of lens movement (e.g., movement of lens 28) needed to bring an object of interest into focus.

Image processing and data formatting circuitry 16 may also be used to compress raw camera image files if desired, such as to Joint Photographic Experts Group (JPEG) format. In a typical arrangement, which is sometimes referred to as a system on chip (SOC) arrangement, image sensor 14 and image processing and data formatting circuitry 16 are implemented on a common integrated circuit. The use of a single integrated circuit to implement image sensor 14 and image processing and data formatting circuitry 16 may help to reduce costs. However, this is merely illustrative. If desired, image sensor 14 and image processing and data formatting circuitry 16 may be implemented using separate integrated circuits. For example, image sensor 14 and image processing and data formatting circuitry 16 may be formed using separate integrated circuits that are stacked (e.g., vertically stacked) relative to one another.

Camera module 12 may convey acquired image data to host subsystems 20 over path 18. In other words, image processing and data formatting circuitry 16 may convey image data to subsystems 20 over path 18. Electronic device 10 typically provides a user with numerous high-level functions. In a computer or cellular telephone, for example, a user may be provided with the ability to run user applications. To implement these functions, host subsystem 20 of electronic device 10 may include storage and processing circuitry 24 and input-output devices 22 such as keypads, keyboards, touch pads, mice, input-output ports, joysticks, and displays. Input-output devices 22 may also include light sources such as light-emitting diodes that may be used in combination with image sensor(s) 14 to obtain time-of-flight depth sensing information. Input-output devices 22 may include, for example, a light source that emits visible or infrared light.

Storage and processing circuitry 24 may include volatile and nonvolatile memory, such as random-access memory, flash memory, hard drives, solid state drives, etc. Storage and processing circuitry 24 may also include microprocessors, microcontrollers, digital signal processors, application specific integrated circuits, or other processing circuits.

Each of the pixels of image sensor 14 may include a photodiode that generates charge in response to light incident on the photodiode and a floating diffusion (FD) region. The FD region may in turn be coupled to readout circuitry in the pixel. Therefore, in operation, the charge generated by the photodiode is transferred to the FD region.

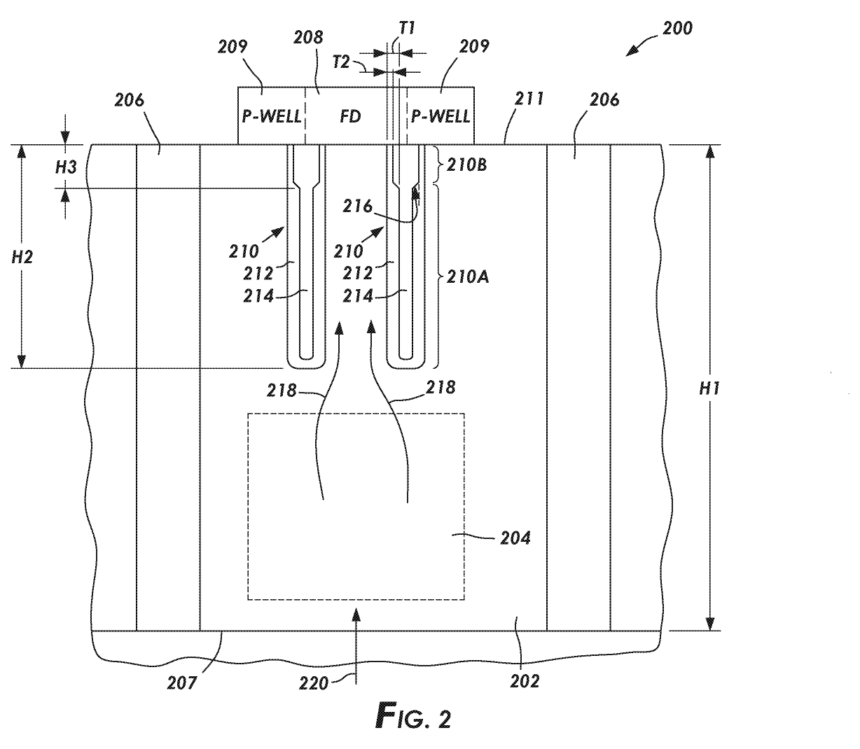

In some embodiments, it may be desirable to include vertical transfer gates that transfer the charge from the photodiode to the FD region. In particular, the vertical transfer gates may reduce the size (e.g., the lateral footprint) of each pixel, and the vertical transfer gates may be designed to steer the charge generated by the photodiode to the FD while preventing spill back to the photodiode when the vertical transfer gates are turned off. Therefore, step shield vertical transfer gates having portions with different gate oxide thicknesses may be used. An illustrative example of an image sensor pixel with step shield vertical transfer gates is shown in FIG. 2.

As shown in FIG. 2, pixel 200, which may be included in an image sensor, such as image sensor 14 of FIG. 1, may include substrate 202. Substrate 202 may be formed from a dielectric material, such as silicon or another suitable semiconductor material.

Photodiode 204 may be formed in substrate 202. Photodiode 204 may include doped portions of substrate 202 (e.g., P-type doped and/or N-type doped portions of a silicon substrate) and/or may include other material, such as doped epitaxial material.

Floating diffusion (FD) region 208, surrounded by P-wells 209, may be formed on a surface of substrate 202, such as surface 211. FD region 208 may overlap photodiode 204. In other words, photodiode 204 may be overlapped by FD region 208.

In the example of FIG. 2, pixel 200 is a backside-illuminated (BSI) image sensor pixel, and surface 211 is the front surface of substrate 202. However, this is merely illustrative. In some embodiments, a pixel may be a frontside-illuminated image sensor pixel, and FD region 208 may be formed on a rear surface of the substrate.

Trenches 206 may separate pixel 200 from adjacent pixels within the image sensor. Trenches 206 may be formed from a dielectric material, such as an oxide. In the example of FIG. 2, trenches 206 are deep-trench isolation (DTI) trenches that extend from back surface 207 to front surface 211. However, this is merely illustrative. In some embodiments, trenches 206 may extend partially within substrate 202. Regardless of how far trenches 206 extend within substrate 202, in some embodiments, trenches 206 may be biased to reduce or prevent crosstalk between adjacent pixels of the image sensor.

Pixel 200 may include vertical transfer gates 210 (e.g., first and second vertical transfer gates 210) interposed between photodiode 204 and FD region 208. Vertical transfer gates 210 may each include gate oxide 212 and semiconductor material 214. Gate oxide 212 may be formed from silicon dioxide or another suitable material. Semiconductor material 214 may be formed from polysilicon or another suitable material.

In the example of FIG. 2, vertical transfer gates 210 are both step shield vertical transfer gates. Therefore, vertical transfer gates 210 may be referred to as step shield vertical transfer gates herein. In particular, each step shield vertical transfer gate 210 has a first portion 210A and a second portion 210B. First portion 210A of each vertical transfer gate 210 is interposed between photodiode 204 and second portion 210B of that vertical transfer gate 210.

First portion 210A may have a first gate oxide thickness T1, and second portion 210B may have a second gate oxide thickness T2. First gate oxide thickness T1 may be, for example, at least 400 angstroms, at least 600 angstroms, at least 1000 angstroms, at least 1500 angstroms, between 500 angstroms and 2000 angstroms, less than 2000 angstroms, or another suitable thickness. Second gate oxide thickness T2 may be, for example, less than 400 angstroms, less than 300 angstroms, between 100 angstroms and 300 angstroms, at least 200 angstroms, at least 25 angstroms, at least 50 angstroms, or another suitable thickness. In general, first gate oxide thickness T1 may be greater than second gate oxide thickness T2. In particular, by forming first portion 210A with a greater gate oxide thickness than second portion 210B, first portion 210A may have a first threshold voltage (Vt) that is higher than a second threshold voltage (Vt) of second portion 210B.

Step shield transfer gates 210 may have height H2, which may be at least 2 microns, at least 3 microns, between 1 micron and 4 microns, less than 5 microns, or another suitable height. Substrate 202 may have height H1 of at least 6 microns, at least 8 microns, between 7 microns and 12 microns, or another suitable height. In some embodiments, height H2 may be less than half of height H1. However, this is merely illustrative. Height H2 may be equal to or greater than half of height H1, if desired.

Second portion 210B may have height H3, which may be less than 1 micron, less than 1.5 microns, between 0.5 microns and 1.5 microns, or another suitable height. In some embodiments height H3 of second portion 210B may be less than half or less than a third of the height of first portion 210A (e.g., height H2 minus height H3). However, this is merely illustrative. Height H3 of second portion 210B may be equal to or greater than half of the height of first portion 210A (e.g., height H2 minus height H3).

First portion 210A may extend from second portion 210B at angle 216. Angle 216 may be at least 30°, at least 35°, 45°, between 35° and 55°, or another suitable angle. In some embodiments, first portion 210A and second portion 210B may have continuous gate oxide portions 212 and semiconductor material portions 214. In other words, gate oxide 212 of first portion 210A may be in physical contact with gate oxide 212 of second portion 210B, and semiconductor material 214 of first portion 210A may be in physical contact with gate oxide 212 of second portion 210B.

In operation, photodiode 204 may generate charge (e.g., photocurrent) in response to incident light 220. To transfer the generated charge to FD region 208, vertical transfer gates 210 may be turned on (e.g., biased using a current). In response to vertical transfer gates 210 being turned on, the charge generated by photodiode 204 may move in direction 218 to FD region 208. In particular, the charge generated along the interface between gate oxide 212 and substrate 202 (e.g., an Si-SiO₂ interface) may be steered in direction 218 toward FD region 208. In this way, step shield vertical transfer gates 210 may selectively transfer the charge from the photodiode to the floating diffusion region in parallel with one another when step shield vertical transfer gates 210 are turned on.

Due to first portion 210A having a thicker gate oxide 212 than second portion 210B, first portion 210A has a higher Vt than second portion 210B. The Vt difference between first portion 210A and second portion 210B helps to steer the charge toward FD region 208 (e.g., due to the potential difference between first portion 210A and second portion 210B). Additionally, the Vt difference pushes the charge toward FD region 208 when vertical transfer gates 210 are turned off due to the internal potential difference of vertical transfer gates 210, preventing spillback of the charge back to photodiode 204. In this way, step shield vertical transfer gates 210 may steer the charge generated by photodiode 204 toward FD region 208 while preventing spillback of the charge to photodiode 204, which may increase the complete charge transfer efficiency between photodiode 204 and FD region 208 and reduce image artifacts caused by incomplete charge transfer such as ghosting and lag.

Although FIG. 2 shows pixel 200 with two step shield vertical transfer gates 210, this is merely illustrative. In some embodiments, pixel 200 may include a single step shield vertical transfer gate 210 to steer the charge generated by photodiode 204 to FD region 208. For example, pixel 200 may have a single vertical transfer gate that is a step shield vertical transfer gate, or pixel 200 may have a step shield vertical transfer gate and another, non-step shield vertical transfer gate. In general, any suitable number of step shield vertical transfer gate(s) 210, other vertical transfer gates, and/or horizontal transfer gates may be incorporated into pixel 200.

Moreover, although FIG. 2 shows FD region 208 being formed on surface 211, this is merely illustrative. In some embodiments, FD region 208 may be formed within (e.g., embedded in) a portion of substrate 202, such as at surface 211.

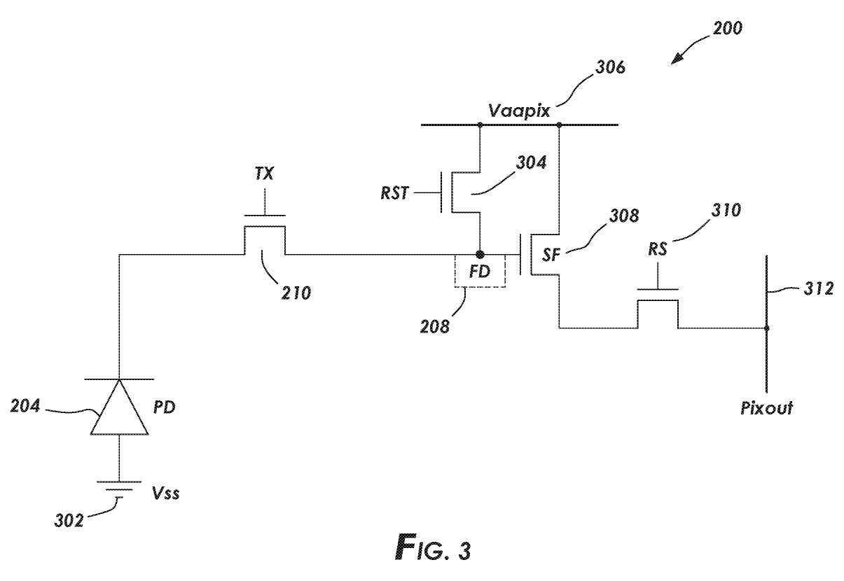

An illustrative circuit diagram of pixel 200 is shown in FIG. 3. As shown in FIG. 3, pixel 200 may have a photodiode PD 204 that is coupled to FD region 208 (also referred to as FD node 208 herein) via a transfer gate 210 (e.g., a step shield vertical transfer gate as shown in FIG. 2). Reset transistor 304, controlled by signal RST, may be coupled between power supply line Vaapix 306 and FD node 208. Source follower transistor SF 308 may have a drain terminal coupled to power supply line Vaapix 306, a gate terminal shorted to FD node 208, and a source terminal coupled to pixel output line Pixout 312 via a row select transistor 310 that is controlled by signal RS. The p-type terminal of photodiode PD 204 may be shorted to ground power supply line Vss 302 (usually via p-type structures). This pixel circuit implementation is merely illustrative. In general, pixel 200 may include any number of photodiodes and/or storage diodes, any number of transfer gates (e.g., two step shield vertical transfer gates) and storage gates, and any number of associated readout/control circuitry.

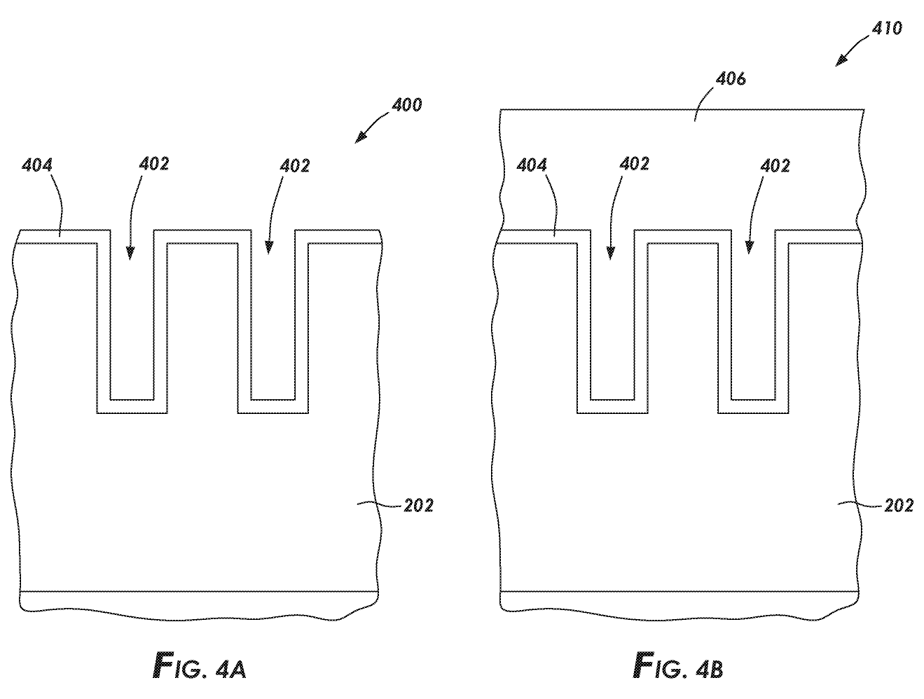

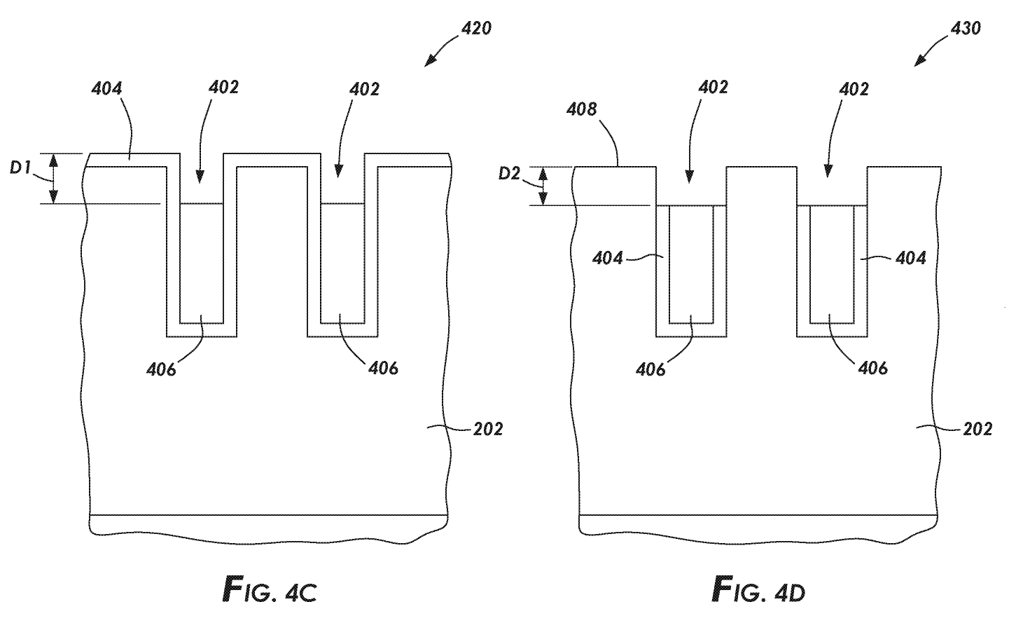

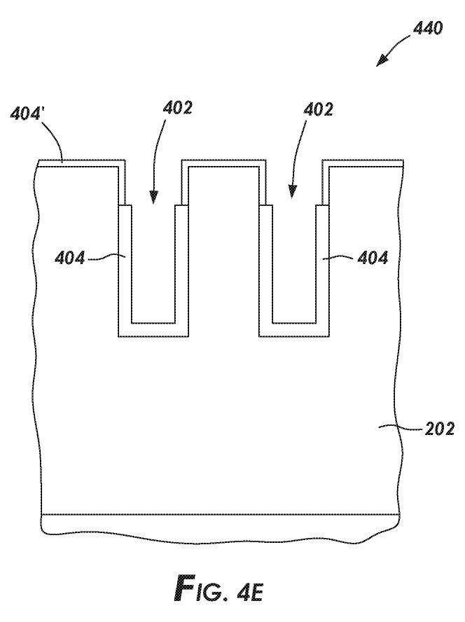

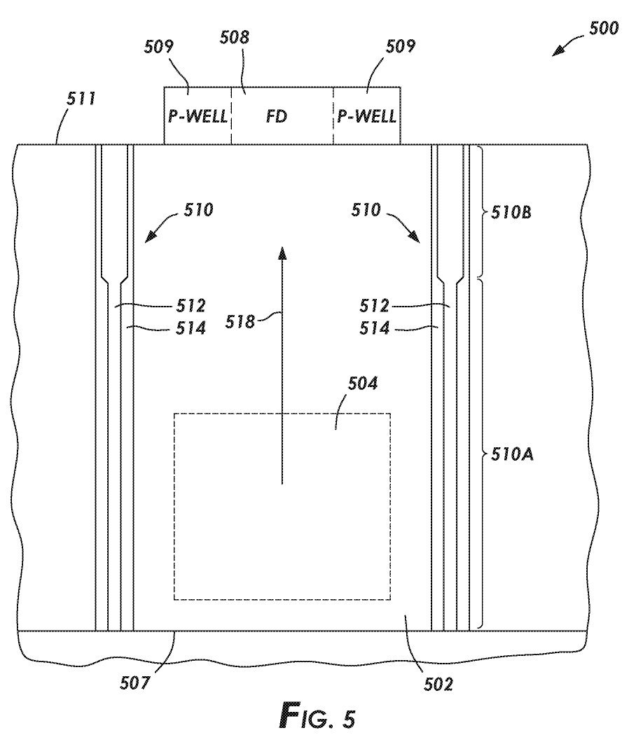

Regardless of the arrangement of a pixel, such as pixel 200, the pixel may include one or more step shield vertical transfer gates, such as step shield vertical transfer gates 210 of FIG. 2. Illustrative method steps that may be used to form step shield vertical transfer gates are shown in FIGS. 4A-4E.

As shown in FIG. 4A, at step 400, substrate 202 may be etched with recesses 402. Recesses 402 may have depths of 5 microns or less, 4 microns or less, 3 microns or less, between 1 micron and 6 microns, at least 2 microns, or another suitable depth into substrate 202. Substrate 202 may be a semiconductor substrate, such as a silicon substrate.

Oxide 404 may be applied to substrate 202, including within recesses 402. Oxide 404 may be a gate oxide, such as silicon dioxide or another suitable oxide. Oxide 404 may be applied with a first thickness, such as a thickness of at least 400 angstroms, at least 600 angstroms, at least 1000 angstroms, at least 1500 angstroms, between 500 angstroms and 2000 angstroms, less than 2000 angstroms, or another suitable thickness.

After oxide 404 has been applied to substrate 202, at step 410 of FIG. 4B, material 406 may be applied to substrate 202, including in recesses 402, on top of oxide 404. Material 406 may be a photoresist, such as an organic photoresist material, may be a polysilicon material, or may be another suitable material. Material 406 may be applied with a thickness of at least 3 microns, at least 2 microns, between 2 microns and 6 microns, less than 5 microns, or another suitable thickness.

After material 406 has been applied, at step 420 of FIG. 4C, material 406 may be etched and cured. For example, material 406 may be etched to a depth D1 from an upper surface of oxide 404 of at least 0.5 microns, at least 0.7 microns, at least 0.85 microns, between 0.6 microns and 1 micron, less than 1.2 microns, or another suitable depth. After material 406 has been etched, it may be cured, such as using an ultraviolet curing process.

Although FIG. 4C shows a single etching of material 406, this is merely illustrative. In some embodiments, material 406 may be etched multiple times. For example, material 406 may be etched to an upper surface of oxide 404, cured, and then etched to depth D1. In general, material 406 may be etched any suitable number of times.

After material 406 has been cured, at step 430 of FIG. 4D, oxide 404 may be etched. For example, oxide 404 may be etched to a depth D2 into each of recesses 402 from surface 408 of substrate 202. Depth D2 may be less than 1 micron, less than 1.5 microns, between 0.5 microns and 1.5 microns, or another suitable depth. Depth D2 may be less than half of the distance into each of the recesses (e.g., the depth of each of the recesses), as an illustrative example.

After oxide 404 has been etched, at step 440 of FIG. 4E, material 406 may be stripped from substrate 202/oxide 404, and additional oxide 404’ may be deposited on oxide 404/substrate 202. Additional oxide 404’ may be deposited with a second thickness of less than 400 angstroms, less than 300 angstroms, between 100 angstroms and 300 angstroms, at least 200 angstroms, at least 25 angstroms, at least 50 angstroms, or another suitable thickness. The second thickness of additional oxide 404’ may be less than half or less than a third of the first thickness of oxide 404, as illustrative examples.

Recesses 402 may be filled with a semiconductor material, such as polysilicon, to form step shield vertical transfer gates, such as step shield vertical transfer gates 210 of FIG. 2. In particular, the step shield vertical transfer gates will have a first portion formed by oxide 404 (plus additional oxide 404’) and a second portion formed by additional oxide 404’. The first portion will have a gate oxide thickness that is thicker than the gate oxide thickness of the second portion. As a result, the first portion will have a higher Vt than the second portion, steering charge from an underlying photodiode to an overlying FD region, as well as preventing spill back when the vertical transfer gates are turned off.

Although FIGS. 4A-4E show etching two recesses into substrate 202 to form two step shield vertical transfer gates, this is merely illustrative. In some embodiments, more recesses may be etched into substrate 202 to form additional vertical transfer gates and/or other structures. If other structures are formed by the recesses, the recesses may optionally be masked prior to etching the oxide in step 430 of FIG. 4D and/or prior to any other suitable steps.

In the examples of FIGS. 2 and 4A-4E, step shield vertical transfer gates are shown as extending partially through a pixel substrate. However, this is merely illustrative. In some embodiments, step shield vertical transfer gates may be deep trench step shield vertical transfer gates. An illustrative example is shown in FIG. 5.

As shown in FIG. 5, pixel 500 may include substrate 502 with back surface 507 and front surface 511, photodiode 504, FD region 508, and P-wells 509, which may correspond to substrate 202 with back surface 207 and front surface 211, photodiode 204, FD region 208, and P-wells 209, respectively, of FIG. 2. In other words, each of these corresponding portions of pixel 500 may be formed from the same materials and function in the same manner as described above in connection with pixel 200 of FIG. 2.

Deep trench step shield vertical transfer gates 510 may extend from back surface 507 of substrate 502 to front surface 511 of substrate 502. Deep trench step shield vertical transfer gates 510 may include first portions 510A having gate oxide 512 with a first thickness and second portions 510B having gate oxide 512 with a second thickness that is less than the first thickness. As a result, deep trench step shield vertical transfer gates 510 may steer charge generated by photodiode 504 in direction 518 to FD region 508 when deep trench step shield vertical transfer gates 510 are turned on and may prevent spill back of the charge into photodiode 504 when deep trench step shield vertical transfer gates 510 are turned off.

Semiconductor material 514 may fill step shield vertical transfer gates 510 and may correspond with semiconductor material 214 of FIG. 2.

Because deep trench step shield vertical transfer gates 510 extend from front surface 511 to back surface 507 of substrate 502, deep trench step shield vertical transfer gates 510 may isolate adjacent pixels within an image sensor, and additional deep trench structures (e.g., trenches 206 of FIG. 2) may be omitted from pixel 500. To prevent crosstalk between adjacent pixels of the image sensor, deep trench step shield vertical transfer gates 510 may be biased. In other words, in addition to biasing deep trench step shield vertical transfer gates 510 to steer the charge generated from photodiode 504 to FD region 508, deep trench step shield vertical transfer gates 510 may be biased to prevent/reduce crosstalk between adjacent pixels.

It will be recognized by one skilled in the art that the present exemplary embodiments may be practiced without some or all of these specific details. In other instances, well-known operations have not been described in detail in order not to unnecessarily obscure the present embodiments.

The foregoing is merely illustrative and various modifications can be made to the described embodiments. The foregoing embodiments may be implemented individually or in any combination.

What is claimed is:

1. An image sensor pixel, comprising:
a floating diffusion region;
a photodiode; and
a step shield vertical transfer gate that is configured to selectively transfer charge from the photodiode to the floating diffusion region.

2. The image sensor pixel of claim 1, wherein the step shield vertical transfer gate comprises a first portion with a first thickness and a second portion with a second thickness that is less than the first thickness.

3. The image sensor pixel of claim 2, wherein the step shield vertical transfer gate comprises a gate oxide, and the gate oxide has the first thickness in the first portion and the second thickness in the second portion.

4. The image sensor pixel of claim 3, wherein the first portion extends from the second portion, and the first portion is interposed between the photodiode and the second portion.

5. The image sensor pixel of claim 4, wherein the first portion has a first height, and the second portion has a second height that is less than the first height.

6. The image sensor pixel of claim 5, wherein second first height is less than half of the first height.

7. The image sensor pixel of claim 4, wherein the step shield vertical transfer gate has a first threshold voltage at the first portion and a second threshold voltage that is less than the first threshold voltage at the second portion.

8. The image sensor pixel of claim 1, wherein the step shield vertical transfer gate is a first step shield vertical transfer gate, the image sensor pixel further comprising:
a second step shield vertical transfer gate that is configured to selectively transfer charge from the photodiode to the floating diffusion region in parallel with the first step shield vertical transfer gate.

9. The image sensor pixel of claim 8, wherein the first step shield vertical transfer gate and the second step shield vertical transfer gate are deep trench step shield vertical transfer gates.

10. The image sensor pixel of claim 1, wherein the photodiode and the step shield vertical transfer gate are formed in a substrate having a first height, and the step shield vertical transfer gate has a second height that is less than half of the first height.

11. A method of forming an image sensor, comprising:
etching recesses in a substrate;
applying an oxide with a first thickness to the substrate;
filling the recesses of the substrate with a material;
etching and curing the material;
etching the oxide a distance into each of the recesses; and
applying additional oxide with a second thickness to the substrate to form step shield vertical transfer gates in the substrate.

12. The method of claim 11, wherein etching the recesses in the substrate comprises etching the recesses with a height that is less than half of a height of the substrate.

13. The method of claim 11, wherein applying the additional oxide with the second thickness comprises applying the additional oxide with a thickness that is less than a third of the first thickness.

14. The method of claim 11, wherein etching the oxide the distance into each of the recesses comprises etching the oxide less than half of the distance into each of the recesses.

15. The method of claim 11, further comprising:
prior to etching the oxide, masking at least some of the recesses.

16. An image sensor, comprising:
a floating diffusion region;
a photodiode overlapped by the floating diffusion region; and
first and second vertical transfer gates that are configured to selectively transfer charge from the photodiode to the floating diffusion region, wherein the first and second vertical transfer gates comprise first portions with first threshold voltages and second portions with second threshold voltages that are less than the first threshold voltages.

17. The image sensor of claim 16, wherein the first portions comprise first gate oxide thicknesses, and the second portions comprise second gate oxide thicknesses that are less than the first gate oxide thicknesses.

18. The image sensor of claim 17, wherein the first and second vertical transfer gates are interposed between the photodiode and the floating diffusion region.

19. The image sensor of claim 18, wherein the first portions are interposed between the photodiode and the second portions.

20. The image sensor of claim 19, wherein the first portions have first heights and the second portions have second heights that are less than the first heights.
